(19) United States
(12) Patent Application Publication
(10) Pub. No.: US 2019/0157248 A1
(43) Pub. Date: May 23, 2019

(54) MICRO LED DISPLAY PANEL WITH NARROW BORDER

(71) Applicant: Century Micro Display Technology (Shenzhen) Co., Ltd., Shenzhen (CN)

(72) Inventors: KUO-SHENG LEE, New Taipei (TW); PO-FU CHEN, New Taipei (TW); CHIH-HAO CHANG, New Taipei (TW)

(21) Appl. No.: 16/195,874

(22) Filed: Nov. 20, 2018

Related U.S. Application Data
(60) Provisional application No. 62/588,434, filed on Nov. 20, 2017.

(51) Int. Cl. H01L 25/075; H01L 27/12

(52) U.S. Cl. CPC H01L 25/0753; H01L 27/124

(57) ABSTRACT

A micro LED display panel includes a substrate, a pixel circuit layer on the substrate, an insulating layer on the pixel circuit layer, at least two micro LEDs on the insulating layer, and at least two first electrodes. The pixel circuit layer defines at least two sub-pixel regions and includes at least two TFTs. At least one TFT is located in each sub-pixel region. Each first electrode is between one micro LED and the insulating layer and extends through the insulating layer to be electrically coupled to one TFT. All of the sub-pixel regions form a main display area of the micro LED display panel. The micro LEDs distribute not only in the main display area, but also outside of the main display area.

### FIELD

The subject matter herein generally relates to a micro LED display panel with a narrow border.

### BACKGROUND

A micro light emitting diode (LED) display panel includes a thin film transistor (TFT) substrate and a plurality of micro LEDs spaced apart from each other on the TFT substrate. The micro LED display panel generally defines a display area and a border area surrounding the display area. All the micro LEDs are located in the display area. However, a display panel with a narrow border or a borderless display panel are in demand.

Therefore, there is room for improvement in the art.

### BRIEF DESCRIPTION OF THE DRAWINGS

Implementations of the present technology will now be described, by way of embodiments, with reference to the attached figures.

FIG. 1 is a plan view of a micro LED display panel according to an embodiment of the present disclosure.

FIG. 2 is a cross-sectional view of part of the micro LED display panel of FIG. 1.

FIG. 3 is an isometric view showing connection between a first electrode layer and a pixel circuit layer of the micro LED display panel.

FIG. 4 is a cross-sectional view of part of a micro LED display panel according to a second embodiment of the present disclosure.

FIG. 5 is an isometric view showing connections between a first electrode layer and a pixel circuit layer of a micro LED display panel according to a third embodiment of the present disclosure.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein may be practiced without these specific details. In other instances, methods, procedures, and components have not been described in detail so as not to obscure the related relevant feature being described. Also, the description is not to be considered as limiting the scope of the embodiments described herein. The drawings are not necessarily to scale and the proportions of certain parts may be exaggerated to better illustrate details and features of the present disclosure.

The term “coupled” is defined as connected, whether directly or indirectly through intervening components, and is not necessarily limited to physical connections. The connection can be such that the objects are permanently coupled or releasably coupled. The term “comprising” when utilized, means “including, but not necessarily limited to”; it specifically indicates open-ended inclusion or membership in the so-described combination, group, series, and the like. The term “micro LED” herein refers to an LED having a size of a few millimeters or less (for example, several millimeters, several hundred micrometers, or less than or equal to 100 micrometers).

### First Embodiment

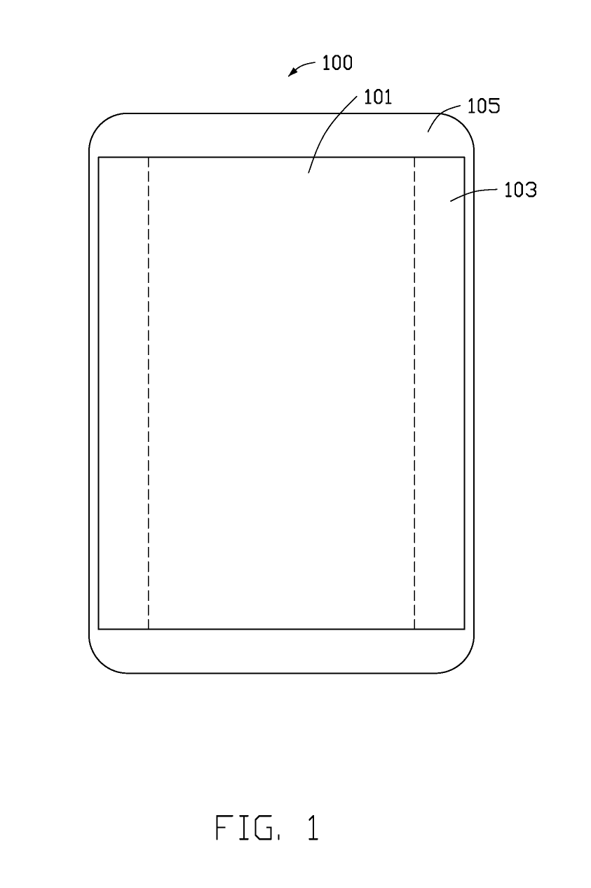

Referring to FIG. 1, a micro LED display panel 100 defines a main display area 101. In the present embodiment, the main display area 101 is a rectangle defined by two dotted lines and two solid lines intersecting with the two dotted lines, as shown in FIG. 1. Two extended display areas 103 are on opposite sides of the main display area 101, and a border area 105 surrounds the main display area 101 and the two extended display areas 103.

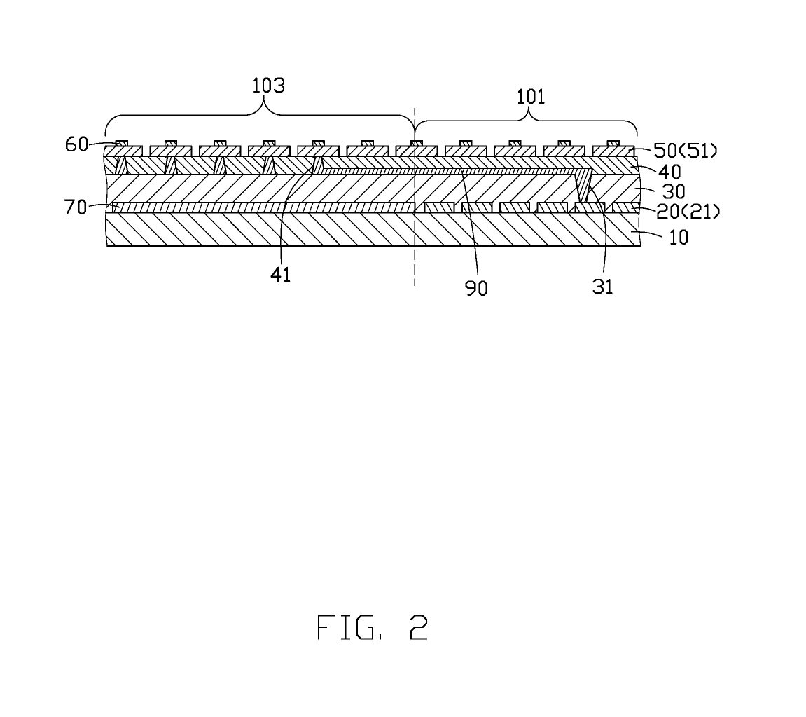

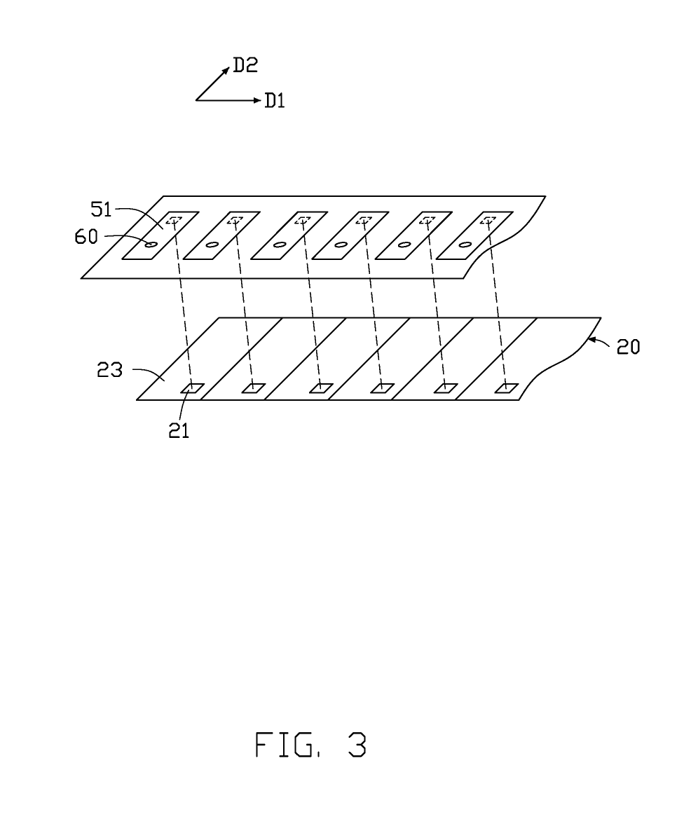

Referring to FIG. 2, the micro LED display panel 100 includes a substrate 10, a pixel circuit layer 20 on the substrate 10, a planar layer 30 on the substrate 10 and covering the pixel circuit layer 20, an insulating layer 40 on the planar layer 30, and a first electrode layer 50 formed on the insulating layer 40. The first electrode layer 50 includes a plurality of first electrodes 51 spaced apart from each other. The micro LED display panel 100 further includes a plurality of micro LEDs 60. Each of the micro LEDs 60 is located on each of the first electrodes 51. In the present embodiment, the micro LEDs 60 are arranged in a matrix, having rows (in a first direction D1 shown in FIG. 3) and columns (in a second direction D2 shown in FIG. 3). Each of the micro LEDs 60 has opposite ends, one end of the micro LED 60 being adjacent to the substrate 10 and coupled to a first electrode 51, and the other end of the micro LED 60 being away from the substrate 10 and coupled to a second electrode (not shown). The first electrodes 51 are also arranged in a matrix, having rows (in the first direction D1 shown in FIG. 3) and columns (in the second direction D2 shown in FIG. 3). When a potential difference is formed between the first electrode 51 and the second electrode, the micro LED 60 emits light. The second electrode is made of a transparent conductive material, and all the micro LEDs 60 may share one second electrode. The second electrode covers the ends of all the micro LEDs 60 away from the substrate 10.

The pixel circuit layer 20 may include thin film transistors (TFTs) 21. Each of the first electrodes 51 is electrically coupled to the pixel circuit layer 20 to drive the micro LEDs 60 to emit light. Specifically, each of the first electrodes 51 is electrically coupled to one TFT 21 of the pixel circuit layer 20.

The pixel circuit layer 20 further includes data lines (not shown) and scan lines (not shown). Each data line is electrically insulated from but crosses the scan lines. The pixel circuit layer 20 defines sub-pixel regions 23 arranged in a matrix according to the data lines and the scan lines, as shown in FIG. 3. Each of the sub-pixel regions 23 is provided with at least one TFT 21. FIG. 1 shows one TFT 21 in each of the sub-pixel regions 23. Each of the sub-pixel regions 23 contains one micro LED 60 and one first electrode 51.

In the present embodiment, all of the sub-pixel regions 23 form the main display area 101 of the micro LED display panel 100. In this disclosure, the micro LEDs 60 are located not only in the main display area 101, but also in the extended display area 103. The first electrodes 51 are located not only in the main display area 101, but also in the extended display area 103.

As shown in FIG. 2, the micro LED display panel 100 further includes a gate driver 70 on the substrate 10 and beside the pixel circuit layer 20. In one embodiment, there may be another gate driver (not shown) located beside the pixel circuit layer 20 opposite to the gate driver 70. Since the gate driver 70 is located on a side of the micro LEDs 60 adjacent to the substrate 10, the gate driver 70 does not block light emitted from the micro LED 60. The gate driver 70 may be located only in the extended display area 103 or in the border area 105 as well as in the extended display area 103.

As shown in FIG. 3, each of the first electrodes 51 is electrically coupled to the TFT 21 in one sub-pixel region 23, but may not be aligned with the TFT 21 that are electrically coupled thereto. A projection of the first electrode 51 on the substrate 10 may partially overlap or not overlap a projection of the TFT 21 electrically coupled to the first electrode 51 on the substrate 10. The further the distance between the first electrode 51 and the TFT 21 electrically coupled to the first electrode 51 the better.

As shown in FIG. 2, the insulating layer 40 and the planar layer 30 are located between the first electrode layer 50 and the pixel circuit layer 20. Via holes are thus needed to be defined in both the insulating layer 40 and the planar layer 30 to achieve electrical connections between the first electrode layer 50 and the pixel circuit layer 20. As shown in FIG. 2, the insulating layer 40 defines a plurality of first via holes 41. Each of the first via holes 41 extends through the insulating layer 40, and corresponds to and aligns with one first electrode 51. The planar layer 30 defines a plurality of second via holes 31, FIG. 2 only shows one second via hole 31. Each of the second via holes 31 extends through the planar layer 30, and corresponds to and aligns with one TFT 21. Since the first electrode 51 is not aligned with the TFT 21 electrically coupled to the first electrode 51, each of the first via holes 41 is not aligned with corresponding one of the second via holes 31. Conductive lines 90 are located between the planar layer 30 and the insulating layer 40, FIG. 2 only shows one conductive line 90. Each of the conductive line 90 extends into a pair of the first via hole 41 and the second via hole 31 (i.e., conductive material is formed in the first via hole 41 and the second via hole 31) to be electrically coupled between the first electrode 51 and the TFT 21. The conductive line 90 and the conductive material in the second via hole 31 may be formed after formation of the planar layer 30 and before the insulating layer 40 is formed on the planar layer 30. The conductive material in the first via hole 41 may be formed after formation of the insulating layer 40.

As shown in FIG. 2, the conductive line 90 extends a greater distance between the planar layer 30 and the insulating layer 40, which indicates that the distance between the first via hole 41 and the corresponding second via hole 31 is greater. The distance between the first electrode 51 and the TFT 21 electrically coupled to the first electrode 51 is greater.

In the present embodiment, the micro LEDs 60 include three different types, emitting red light, blue light, and green light. In the present embodiment, each of the micro LEDs 60 is a conventional micro LED including a P-type doped light emitting layer (not shown), an active layer (not shown), and an N-type doped light emitting layer (not shown). The active layer is located between the P-type doped light emitting layer and the N-type doped light emitting layer. The P-type doped light emitting layer is relatively close to the first electrode 51, the N-type doped light emitting layer is relatively far from the first electrode 51. Alternatively, the N-type doped light emitting layer can be relatively close to the first electrode 51, and the P-type doped light emitting layer can be relatively far from the first electrode 51.

As shown in FIG. 3, a row of first electrodes 51 arranged in the first direction D1 and a row of electrically coupled sub-pixel regions 23 in same direction have a positional relationship such that the row of first electrodes 51 partially overlaps the row of sub-pixel regions 23 both in the first direction D1 and in the second direction D2.

Since the micro LEDs 60 extend outside of the main display area 101 in the extended display area 103, the display area of the micro LED display panel 100 also extends outside the main display area 101 to the extended display area 103. A narrower border, or even no border, is thus achieved.

### Second Embodiment

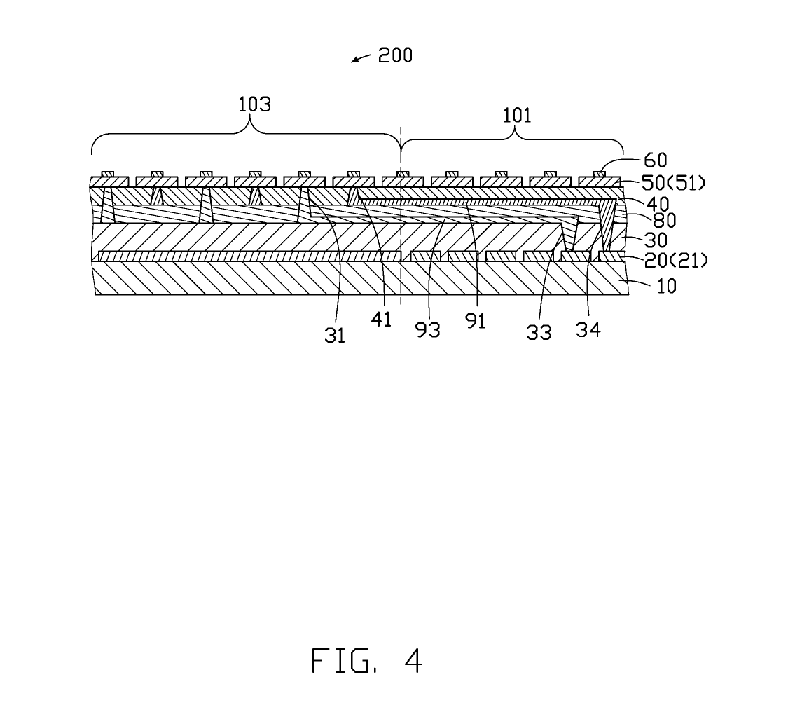

FIG. 4 illustrates a micro LED display panel 200 according to a second embodiment. The micro LED display panel 200 is substantially the same as the micro LED display panel 100 of first embodiment. The micro LED display panel 200 also includes a substrate 10, a pixel circuit layer 20 on the substrate 10, a planar layer 30 on the substrate 10 and covering the pixel circuit layer 20, an insulating layer 40 on the planar layer 30, and a first electrode layer 50 formed on the insulating layer 40. The difference between the micro LED display panel 200 and the micro LED display panel 100 is that the micro LED display panel 200 further includes an additional insulating layer 80 between the insulating layer 40 and the planar layer 30.

As shown in FIG. 4, since the insulating layer 40, the planar layer 30, and the additional insulating layer 80 are located between the first electrode 51 and the pixel circuit layer 20, it is necessary to define via holes in the insulating layer 40, the planar layer 30, and the additional insulating layer 80 to achieve electrical connection between the first electrode layer 50 and the pixel circuit layer 20. As shown in FIG. 4, the insulating layer 40 defines two kinds of via holes. These two kinds are first via holes 41 and third via holes 31. Each of the first via holes 41 corresponds to and aligns with one first electrode 51 and extends through the insulating layer 40 only. Each of the third via holes 31 corresponds to and aligns with one first electrode 51 and extends through both the insulating layer 40 and the additional insulating layer 80. The planar layer 30 defines two kinds of via holes, these being second via holes 34 and fourth via holes 33. Each fourth via hole 33 corresponds to and aligns with one TFT 21 and extends through the planar layer 30 only. Each second via hole 34 corresponds to and aligns with one TFT 21 and extends through both the planar layer 30 and the additional insulating layer 80.

As shown in FIG. 4, each of the first via holes 41 corresponds to a second via hole 34, and each of the third via holes 31 corresponds to a fourth via hole 33. Since the first electrode 51 does not align with the TFT 21 electrically coupled to the first electrode 51, each of the first via holes 41 does not align with a second via hole 34, and each of the third via holes 31 does not align with the corresponding fourth via hole 33. First conductive lines 91 are located between the additional insulating layer 80 and the insulating layer 40, FIG. 4 only shows one first conductive line 91. Each of the first conductive lines 91 extends into one first via hole 41 and one second via hole 34 (i.e., conductive material is formed in the first via hole 41 and the second via hole 34) so as to be electrically coupled between the first electrode 51 and the TFT 21. Second conductive lines 93 are located between the planar layer 30 and the insulating layer 40, FIG. 4 only shows one second conductive line 93. Each of the second conductive lines 93 extends into one third via hole 31 and one fourth via hole 33 (i.e., a conductive material is formed in the third via hole 31 and the fourth via hole 33) so as to be electrically coupled between the first electrode 51 and the TFT 21.

The second conductive lines 93 and conductive material in the fourth via holes 33 may be formed after the forming of the planar layer 30 and before the forming of the additional insulating layer 80 and the insulating layer 40. The first conductive lines 91 and conductive material in the second via holes 34 may be formed after the additional insulating layer 80 is formed but before the insulating layer 40 is formed. Conductive material in the first via holes 41 and the third via holes 31 may be formed after the formation of the insulating layer 40.

### Third Embodiment

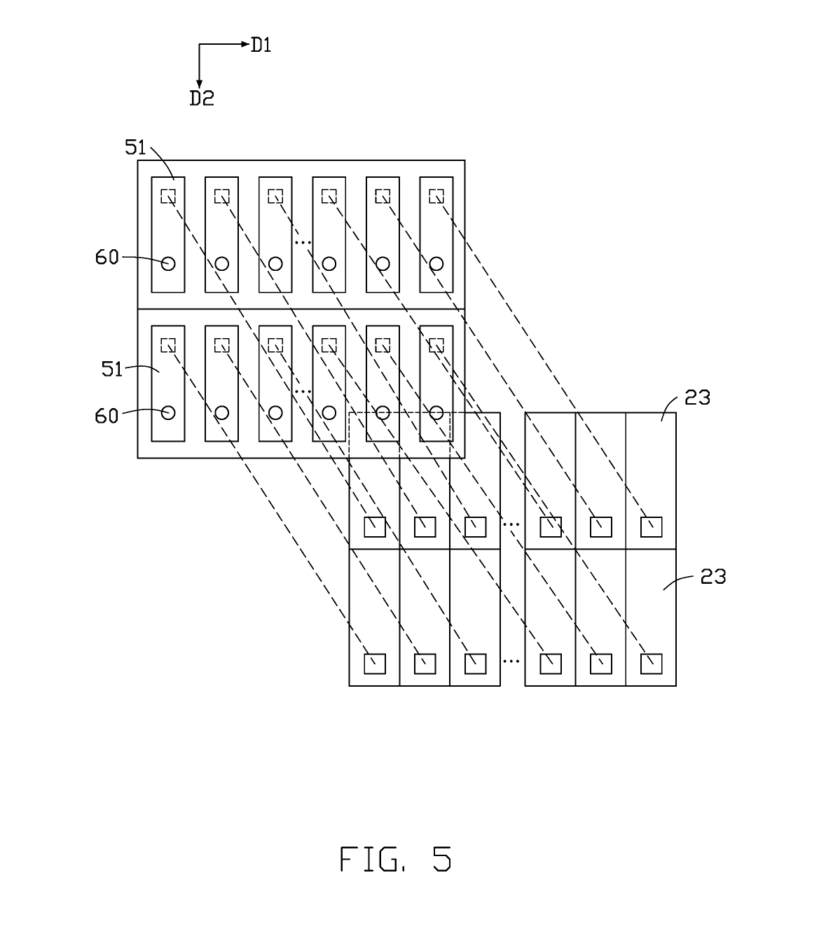

FIG. 5 illustrates connections between first electrodes 51 and a pixel circuit layer 20 of the micro LED display panel (not shown) according to a third embodiment of the present disclosure.

The micro LED display panel in the present embodiment is substantially the same as the micro LED display panel 100 of first embodiment. The micro LED display panel also includes a substrate (not shown), a pixel circuit layer 20 on the substrate, a planar layer (not shown) on the substrate and covering the pixel circuit layer 20, an insulating layer (not shown) on the planar layer, and a first electrode layer (not shown) formed on the insulating layer. The difference between the micro LED display panel in the present embodiment and the micro LED display panel 100 is that a row of first electrodes 51 arranged in the first direction D1 does not overlap the row of sub-pixel regions 23 electrically coupled thereto, in directions D1 and D2. In the first embodiment, the row of first electrodes 51 does partially overlap the row of sub-pixel regions 23 that is electrically coupled to the row of first electrodes 51 both in the first direction D1 and the second direction D2. For the sake of clarity, FIG. 5 only shows two rows of first electrodes 51 and two rows of sub-pixel regions 23. The electrical connections between them are represented by straight dashed lines. In the actual display device, the micro LED display panel has many rows of first electrodes 51 and many rows of sub-pixel regions 23.

It is to be understood, even though information and advantages of the present embodiments have been set forth in the foregoing description, together with details of the structures and functions of the present embodiments, the disclosure is illustrative only; changes may be made in detail, especially in matters of shape, size, and arrangement of parts within the principles of the present embodiments to the full extent indicated by the plain meaning of the terms in which the appended claims are expressed.

What is claimed is:

1. A micro light emitting diode (LED) display panel, comprising:
a substrate;
a pixel circuit layer on the substrate, the pixel circuit layer defining at least two sub-pixel regions and comprising at least two thin film transistors (TFTs), at least one of the at least two TFTs being located in each of the sub-pixel regions;
an insulating layer on the pixel circuit layer;
at least two micro LEDs on the insulating layer; and
at least two first electrodes, each of the at least two first electrodes being between one of the micro LEDs and the insulating layer and extending through the insulating layer to be electrically coupled to one of the TFTs;
wherein all of the sub-pixel regions define a main display area of the micro LED display panel; the micro LEDs distribute in and outside of the main display area.

2. The micro LED display panel of claim 1, wherein a projection of each of the first electrodes on the substrate partially overlaps or does not overlap a projection of the one TFT that is electrically coupled the first electrode.

3. The micro LED display panel of claim 1, further comprising a planar layer on the substrate, the planar layer covering the pixel circuit layer, wherein the insulating layer is formed on a side of the planar layer away from the substrate.

4. The micro LED display panel of claim 3, wherein the insulating layer defines at least two first via holes; each of the at least two first via holes extends through the insulating layer and aligns with one of the first electrodes; the planar layer defines at least two second via holes; each of the at least two second via holes extends through the planar layer and aligns with one of the TFTs; at least two conductive lines are located between the planar layer and the insulating layer; each of the at least two conductive lines extends into one of the first via holes and a corresponding one of the second via holes to be electrically coupled between one of the first electrodes and one of the TFTs.

5. The micro LED display panel of claim 4, wherein the first via hole and the second via hole that both coupled to one same conductive line are not aligned with each other.

6. The micro LED display panel of claim 3, further comprising an additional insulating layer between the insulating layer and the planar layer.

7. The micro LED display panel of claim 6, wherein the insulating layer defines at least two first via holes, each of the two first via holes aligns with one first electrode and extends through the insulating layer; the additional insulating layer defines at least two second via holes, each of the at least two second via holes aligns with one of the TFTs and extends through both the additional insulating layer and the planar layer; at least two first conductive lines are located between the additional insulating layer and the insulating layer; each of the two first conductive lines extends into one of the first via holes and corresponding one of the second via holes to be electrically coupled between one of the first electrodes and one of the TFTs.

8. The micro LED display panel of claim 7, wherein the first via hole and the second via hole both coupled to a same one of the first conductive lines are not aligned with each other.

9. The micro LED display panel of claim 7, wherein the insulating layer defines at least two third via holes, each of the at least two third via holes aligns with one of the first electrodes and extends through both the insulating layer and the additional insulating layer; the planar layer defines at least two fourth via holes, each of the at least two fourth via holes aligns with one of the TFTs and extends through the planar layer; at least two second conductive lines are located between the additional insulating layer and the planar layer; each of the second conductive lines extends into one of the third via holes and a corresponding one of the fourth via holes to be electrically coupled between one of the first electrodes and one of the TFTs.

10. The micro LED display panel of claim 9, wherein the third via hole and the fourth via hole both coupled to a same one of the second conductive lines are not aligned with each other.

11. The micro LED display panel of claim 1, wherein all of the first electrodes are arranged in a matrix having at least two rows each in a first direction and at least two columns each in a second direction, the second direction intersects with the first direction; all of the sub-pixel regions are arranged in a matrix having at least two rows each in the first direction and at least two columns each in the second direction; each of the at least two rows of sub-pixel regions partially overlaps one of the at least two rows of first electrodes that are electrically coupled to the TFTs in the at least two rows of sub-pixel regions.

12. The micro LED display panel of claim 1, wherein all of the first electrodes are arranged in a matrix having at least two rows each in a first direction and at least two columns each in a second direction, the second direction intersects with the first direction; all of the sub-pixel regions are arranged in a matrix having at least two rows each in the first direction and at least two columns each in the second direction; each of the at least two rows of sub-pixel regions does not overlap one row of first electrodes that are electrically coupled to the TFTs in the row of sub-pixel regions.
